(19) United States
(12) Patent Application Publication
(10) Pub. No.: US 2026/0058108 A1
(43) Pub. Date: Feb. 26, 2026

(54) MEMBER IN A SEMICONDUCTOR MANUFACTURING APPARATUS AND MEMBER MANUFACTURING METHOD

(71) Applicant: Tokyo Electron Limited, Tokyo (JP)

(72) Inventors: Nobuyuki NAGAYAMA, Miyagi (JP); Kazuki MOYAMA, Miyagi (JP); Mamoru MIURA, Miyagi (JP)

(73) Assignee: Tokyo Electron Limited, Tokyo (JP)

(21) Appl. No.: 19/373,878

(22) Filed: Oct. 30, 2025

Related U.S. Application Data
(63) Continuation of application No. PCT/JP2024/015998, filed on Apr. 24, 2024.

(30) Foreign Application Priority Data
May 8, 2023 (JP) 2023-076689

(51) Int. Cl. H01J 37/32; H01L 21/683

(52) U.S. Cl. CPC H01J 37/32724; H01J 37/32541; H01L 21/6831; H01J 37/32091

(57) ABSTRACT

A member used in a semiconductor manufacturing apparatus includes a first member, a second member, and a sealing layer disposed between the first member and the second member. The first member has a plurality of first openings, and the second member has a plurality of second openings respectively corresponding to the plurality of first openings. The sealing layer has a plurality of through holes respectively corresponding to at least two first openings among the plurality of first openings. The at least two first openings respectively communicate with at least two corresponding second openings via the plurality of through holes.

### CROSS-REFERENCE TO RELATED APPLICATIONS

This application is a continuation application of International Application No. PCT/JP2024/015998, filed on Apr. 24, 2024 which claims the benefit of priority of the prior Japanese Patent Application No. 2023-076689, filed on May 8, 2023, the entire contents of which are incorporated herein by reference.

### FIELD

One or more embodiments of the present disclosure relate to a member and a member manufacturing method.

### BACKGROUND

Japanese Laid-open Patent Publication 2008-187102 discloses a substrate processing apparatus which is “a substrate processing apparatus 10 in which a stage 13 has a sealing surface 20 and a stage through hole 27 opened on the sealing surface 20, a base arm 18 movable toward the stage 13 has an arm through hole 28 facing the stage through hole 27, a female screw portion 29 is formed on a side surface of the arm through hole 28, a pusher pin 17 fitted into the stage through hole 27 and the arm through hole 28 has a male screw portion 30 positioned on a side of the base arm 18 that is opposite to the stage 13, and when the pusher pin 17 moves upward and an O-ring 21 disposed to surround a flange 35 of the pusher pin 17 and an opening of the sealing surface 20 is separated and then the base arm 18 moves downward, an end portion 29b of the female screw portion 29 abuts on an end portion 30a of the male screw portion 30″.

The present disclosure provides a member that is easy to assemble.

### SUMMARY

According to an aspect of an embodiment, a member used in a semiconductor manufacturing apparatus includes a first member, a second member, and a sealing layer disposed between the first member and the second member. The first member has a plurality of first openings. The second member has a plurality of second openings respectively corresponding to the plurality of first openings. The sealing layer has a plurality of through holes respectively corresponding to at least two of the plurality of first openings. The at least two first openings respectively communicate with at least two corresponding second openings via the plurality of through holes.

### BRIEF DESCRIPTION OF DRAWINGS

FIG. 1 is a diagram for describing a configuration example of a capacitively-coupled plasma processing apparatus;

FIG. 2 is a cross-sectional view illustrating an example of a detailed structure of a substrate support part;

FIG. 3 is a view illustrating an example of an upper surface of a support base;

FIG. 4A is a view illustrating an example of a sealing layer disposed on the support base;

FIG. 4B is an enlarged view illustrating an example of a positional relationship between an opening of the support base and an opening of the sealing layer;

FIG. 4C is a view illustrating another example of the sealing layer disposed on the support base;

FIG. 5 is a view illustrating an example of a lower surface of a radio frequency (RF) plate;

FIG. 6 is a view illustrating an example of an upper surface of the RF plate;

FIG. 7 is a view illustrating an example of a sealing layer disposed on the RF plate;

FIG. 8 is a view illustrating an example of a lower surface of a base;

FIG. 9 is a flowchart illustrating an example of a procedure of manufacturing a body part of the substrate support part;

FIG. 10 is a cross-sectional view illustrating an example of a thickness distribution of a first sealing layer applied to the upper surface of the support base;

FIG. 11 is a cross-sectional view illustrating an example of a state in which the support base and the RF plate are fastened with the first sealing layer interposed therebetween;

FIG. 12 is a flowchart illustrating another example of the procedure of manufacturing the body part of the substrate support part;

FIG. 13 is a schematic cross-sectional view illustrating an example of a structure of a shower head.

### DETAILED DESCRIPTION

Hereinafter, one or more embodiments of a member and a member manufacturing method will be described in detail with reference to the drawings. Note that the disclosed member and member manufacturing method are not limited by the following one or more embodiments.

A structure such as a placing pedestal on which a substrate is placed is provided in a processing apparatus that processes the substrate. The placing pedestal is formed by stacking members having various functions. In addition, the placing pedestal is formed with a channel through which a heat transfer medium for controlling a temperature of the substrate placed on the placing pedestal flows, a cavity for disposing an electric wiring and a lift pin, and the like. Such a channel and cavity are formed in each member forming the placing pedestal, and a channel and a cavity having desired sizes are formed by overlapping the respective members.

However, if there is a gap in a contact surface between the members, a heat medium flowing through the channel leaks into the gap between the members. In addition, also in the cavity for disposing the electric wiring and the lift pin, gas that has entered the cavity may leak through the gap between the members. Therefore, an O-ring is disposed on the contact surface between the members and around the channel or the like.

However, in a case where the O-ring is disposed around the channel or the like, it is necessary to perform machining for forming a recess having a shape along a shape of the O-ring at a place where the O-ring is disposed in order to prevent displacement of the O-ring. In addition, in a case where a plurality of channels and the like are provided, it is necessary to perform the machining for forming the recess having the shape along the shape of the O-ring for each of the channels and the like. Therefore, the structure of the placing pedestal becomes complicated, as a result of which it is difficult to easily manufacture the placing pedestal.

Therefore, the present disclosure provides a member that is easy to manufacture.

### Configuration of Plasma Processing System

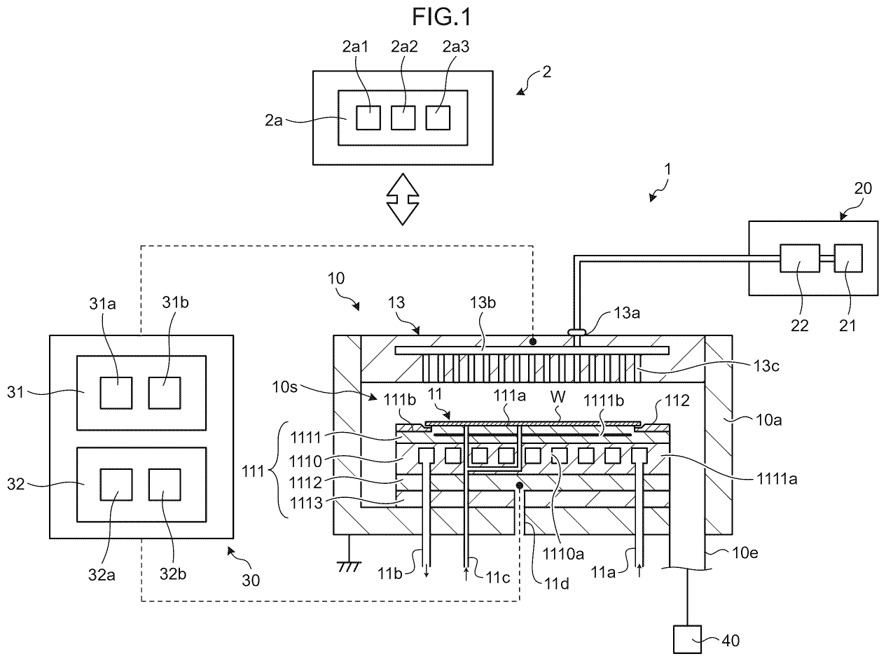

Hereinafter, a configuration example of a plasma processing system will be described. FIG. 1 is a diagram for describing a configuration example of a capacitively-coupled plasma processing apparatus.

The plasma processing system includes a capacitively-coupled plasma processing apparatus 1 and a controller 2. The plasma processing apparatus 1 is an example of a semiconductor manufacturing apparatus. The capacitively-coupled plasma processing apparatus 1 includes a plasma processing chamber 10, a gas supply part 20, a power supply 30, and an exhaust system 40. Further, the plasma processing apparatus 1 includes a substrate support part 11 and a gas introduction part. The gas introduction part is configured to introduce at least one process gas into the plasma processing chamber 10. The gas introduction part includes a shower head 13. The substrate support part 11 is disposed in the plasma processing chamber 10. The shower head 13 is disposed above the substrate support part 11. In one or more embodiments, the shower head 13 forms at least a portion of a ceiling of the plasma processing chamber 10. The plasma processing chamber 10 has a plasma processing space 10s defined by the shower head 13, a side wall 10a of the plasma processing chamber 10, and the substrate support part 11. The plasma processing chamber 10 has at least one gas supply port for supplying at least one process gas to the plasma processing space 10s and at least one gas discharge port for discharging the gas from the plasma processing space. The plasma processing chamber 10 is grounded. The shower head 13 and the substrate support part 11 are electrically insulated from a case of the plasma processing chamber 10.

The substrate support part 11 includes a body part 111 and a ring assembly 112. The body part 111 is an example of the placing pedestal. The body part 111 has a central region 111a for supporting a substrate W and an annular region 111b for supporting the ring assembly 112. A wafer is an example of the substrate W. The annular region 111b of the body part 111 surrounds the central region 111a of the body part 111 in plan view. The substrate W is disposed on the central region 111a of the body part 111, and the ring assembly 112 is disposed on the annular region 111b of the body part 111 so as to surround the substrate W on the central region 111a of the body part 111. Therefore, the central region 111a is also referred to as a substrate support surface for supporting the substrate W, and the annular region 111b is also referred to as a ring support surface for supporting the ring assembly 112.

In one or more embodiments, the body part 111 includes a base 1110, an electrostatic chuck 1111, a radio frequency (RF) plate 1112, and a support base 1113. The base 1110 is an example of a cooling plate. The support base 1113 is made of an insulating material and is disposed at a bottom portion of the plasma processing chamber 10. The RF plate 1112 is disposed on the support base 1113. The RF plate 1112 includes a conductive member. The conductive member of the RF plate 1112 may function as a lower electrode. The base 1110 is disposed on the RF plate 1112. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the central region 111a. In one or more embodiments, the ceramic member 1111a also has the annular region 111b. Another member surrounding the electrostatic chuck 1111, such as an annular electrostatic chuck or an annular insulating member, may have the annular region 111b. In this case, the ring assembly 112 may be disposed on the annular electrostatic chuck or the annular insulating member, or may be disposed on both the electrostatic chuck 1111 and the annular insulating member. In addition, at least one radio frequency (RF)/direct current (DC) electrode coupled to an RF power supply 31 and/or a DC power supply 32 described below may be disposed in the ceramic member 1111a. In this case, at least one RF/DC electrode functions as a lower electrode. In a case where a bias RF signal and/or DC signal described below is provided to at least one RF/DC electrode, the RF/DC electrode is also referred to as a bias electrode. The conductive member of the RF plate 1112 and at least one RF/DC electrode may function as a plurality of lower electrodes. In addition, the electrostatic electrode 1111b may function as a lower electrode. Therefore, the substrate support part 11 includes at least one lower electrode.

The ring assembly 112 includes one or more annular members. In one or more embodiments, the one or more annular members include one or more edge rings and at least one cover ring. The edge ring is formed of a conductive material or an insulating material, and the cover ring is formed of an insulating material.

The substrate support part 11 may include a temperature adjustment module configured to adjust at least one of temperatures of the electrostatic chuck 1111, the ring assembly 112, and the substrate W to a target temperature. The temperature adjustment module may include a heater, a heat transfer medium, a channel 1110a, or a combination thereof. A heat transfer fluid such as brine or gas is supplied to the channel 1110a through a cavity 11a serving as a channel. Then, the heat transfer fluid flowing in the channel 1110a is returned to an external apparatus that controls a temperature of the heat transfer medium via a cavity 11b serving as a channel. The temperature of the heat transfer medium flowing through the channel 1110a is controlled to be, for example, lower than 0° C. In one or more embodiments, the channel 1110a is formed in the base 1110 and one or more heaters are disposed in the ceramic member 1111a of the electrostatic chuck 1111. Further, the substrate support part 11 includes a heat transfer gas supply part configured to supply heat transfer gas to a gap between a reverse face of the substrate W and the central region 111a. The heat transfer gas is supplied to the gap between the reverse face of the substrate W and the central region 111a via a cavity 11c serving as a channel for the heat transfer gas.

The shower head 13 is configured to introduce at least one process gas from the gas supply part 20 into the plasma processing space 10s. The shower head 13 includes at least one gas supply port 13a, at least one gas diffusion chamber 13b, and a plurality of gas introduction ports 13c. The process gas supplied to the gas supply port 13a passes through the gas diffusion chamber 13b and is introduced into the plasma processing space 10s through the gas introduction port 13c. In addition, the shower head 13 includes at least one upper electrode. The gas introduction part may include one or more side gas injectors (SGIs) attached to one or more openings formed in the side wall 10a in addition to the shower head 13.

The gas supply part 20 may include at least one gas source 21 and at least one flow controller 22. In one or more embodiments, the gas supply part 20 is configured to supply at least one process gas from each corresponding gas source 21 to the shower head 13 via each corresponding flow controller 22. Each flow controller 22 may include, for example, a mass flow controller or a pressure control type flow controller. In addition, the gas supply part 20 may include one or more flow modulation devices that modulate or pulse a flow volume of at least one process gas.

The power supply 30 includes an RF power supply 31 coupled to the plasma processing chamber 10 via at least one impedance matching circuit. The RF power supply 31 is configured to provide at least one RF signal (RF power) to at least one lower electrode and/or at least one upper electrode. As a result, plasma is formed from at least one process gas supplied to the plasma processing space 10s. Accordingly, the RF power supply 31 may function as at least a portion of a plasma generation part configured to generate the plasma from one or more process gases in the plasma processing chamber 10. In addition, as the bias RF signal is supplied to at least one lower electrode, a bias potential is generated in the substrate W, and ion components in the formed plasma can be drawn into the substrate W.

In one or more embodiments, the RF power supply 31 includes a first RF generation part 31a and a second RF generation part 31b. The first RF generation part 31a is coupled to at least one lower electrode and/or the at least one upper electrode via at least one impedance matching circuit and is configured to generate a source RF signal (source RF power) for plasma generation. In one or more embodiments, the source RF signal has a frequency in a range of 10 MHz to 150 MHz. In one or more embodiments, the first RF generation part 31a may be configured to generate a plurality of source RF signals having different frequencies. The generated one or more source RF signals are provided to at least one lower electrode and/or the at least one upper electrode.

The second RF generation part 31b is coupled to at least one lower electrode via at least one impedance matching circuit and is configured to generate a bias RF signal (bias RF power). A frequency of the bias RF signal may be the same as or different from the frequency of the source RF signal. In one or more embodiments, the bias RF signal has a lower frequency than the frequency of the source RF signal. In one or more embodiments, the bias RF signal has a frequency in a range of 100 kHz to 60 MHz. In one or more embodiments, the second RF generation part 31b may be configured to generate a plurality of bias RF signals having different frequencies. The generated one or more bias RF signals are provided to at least one lower electrode. Further, in one or more embodiments, at least one of the source RF signal and the bias RF signal may be pulsed. In a case where the RF signal (RF power) is supplied from the RF power supply 31 to the lower electrode, the RF signal (RF power) is supplied to the lower electrode via an electric wiring disposed in a cavity 11d formed in the support base 1113 and the bottom portion of the plasma processing chamber 10. The electric wiring is an example of a structure disposed in the cavity 11d.

The power supply 30 may also include a DC power supply 32 coupled to the plasma processing chamber 10. The DC power supply 32 includes a first DC generation part 32a and a second DC generation part 32b. In one or more embodiments, the first DC generation part 32a is connected to at least one lower electrode and is configured to generate a first DC signal. The generated first DC signal is applied to at least one lower electrode. In one or more embodiments, a second DC generation part 32b is connected to at least one upper electrode and is configured to generate a second DC signal. The generated second DC signal is applied to at least one upper electrode. In a case where the DC signal is applied from the DC power supply 32 to the lower electrode, the DC signal is applied to the lower electrode via the electric wiring disposed in the cavity 11d formed in the support base 1113 and the bottom portion of the plasma processing chamber 10.

In one or more embodiments, at least one of the first and second DC signals may be pulsed. In this case, a sequence of voltage pulses is applied to at least one lower electrode and/or at least one upper electrode. A voltage pulse may have a pulse waveform of a rectangle, a trapezoid, a triangle, or a combination thereof. In one or more embodiments, a waveform generation part for generating a sequence of the voltage pulses from the DC signal is connected between the first DC generation part 32a and at least one lower electrode. Therefore, the first DC generation part 32a and the waveform generation part form a voltage pulse generation part. In a case where the second DC generation part 32b and the waveform generation part form the voltage pulse generation part, the voltage pulse generation part is connected to at least one upper electrode. The voltage pulse may have a positive polarity or a negative polarity. The sequence of the voltage pulses may also include one or more positive voltage pulses and one or more negative voltage pulses within one period. The first and second DC generation parts 32a and 32b may be provided in addition to the RF power supply 31, and the first DC generation part 32a may be provided instead of the second RF generation part 31b.

The exhaust system 40 can be connected to a gas discharge port 10e provided, for example, at the bottom portion of the plasma processing chamber 10. The exhaust system 40 may include a pressure regulating valve and a vacuum pump. A pressure in the plasma processing space 10s is adjusted by the pressure regulating valve. The vacuum pump may include a turbomolecular pump, a dry pump, or a combination thereof.

The controller 2 processes computer-executable instructions that cause the plasma processing apparatus 1 to perform various processes described in the present disclosure. The controller 2 can be configured to control each element of the plasma processing apparatus 1 so as to perform various processes described herein. In one or more embodiments, a part of or the entire controller 2 may be included in the plasma processing apparatus 1. The controller 2 may include a processing unit 2a1, a storage 2a2, and a communication interface 2a3. The controller 2 is implemented by, for example, a computer 2a. The processing unit 2a1 can be configured to perform various control operations by reading a program from the storage 2a2 and executing the read program. The program may be stored in the storage 2a2 in advance or may be acquired via a medium when necessary. The acquired program is stored in the storage 2a2, and is read from the storage 2a2 and executed by the processing unit 2a1. The medium may be various storage media readable by the computer 2a, or may be a communication line connected to the communication interface 2a3. The processing unit 2a1 may be a central processing unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN). The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium, such as a CD-ROM or DVD, and/or the memory of a FPGA or ASIC.

### Structure of Substrate Support Part 11

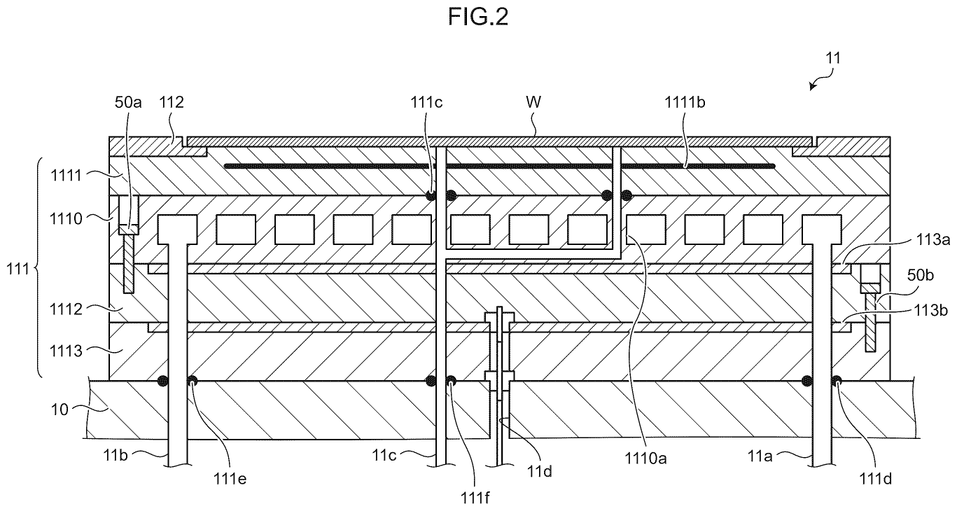

FIG. 2 is a cross-sectional view illustrating an example of a detailed structure of the substrate support part 11. In one or more embodiments, the body part 111 of the substrate support part 11 includes the base 1110, the electrostatic chuck 1111, the RF plate 1112, and the support base 1113. In a relationship between the base 1110 and the RF plate 1112, a portion including the base 1110 and the RF plate 1112 is an example of the member, the RF plate 1112 is an example of a first member, and the base 1110 is an example of a second member. In a relationship between the RF plate 1112 and the support base 1113, the support base 1113 is an example of the first member, and the RF plate 1112 is an example of the second member.

The support base 1113 is formed with the cavity 11a and the cavity 11b serving as the channels for allowing the heat transfer medium to flow, the cavity 11c serving as the channel for allowing the heat transfer gas to flow, and the cavity 11d in which the electric wire for transmitting an electric signal such as the RF signal is disposed.

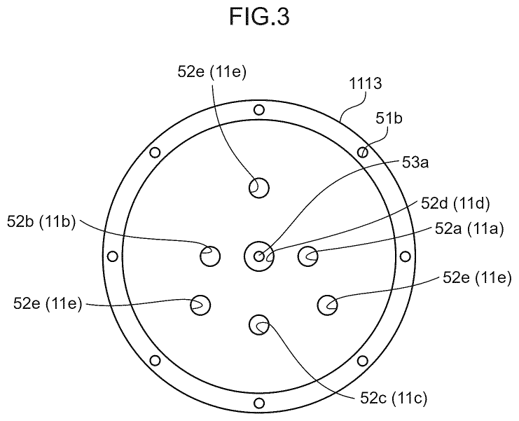

FIG. 3 is a view illustrating an example of an upper surface of the support base 1113. On the upper surface of the support base 1113, for example, as illustrated in FIG. 3, an opening 52a corresponding to the cavity 11a, an opening 52b corresponding to the cavity 11b, an opening 52c corresponding to the cavity 11c, and an opening 52d corresponding to the cavity 11d are formed. A connector 53a is provided in the opening 52d. The connector 53a is connected to a connector 53b of the RF plate 1112 placed on the support base 1113. A plurality of screw holes 51b into which screws 50b for fastening the support base 1113 and the RF plate 1112 are inserted are formed in a peripheral edge portion of the support base 1113.

Although not illustrated in FIG. 2, a plurality of (three in the example of FIG. 3) cavities 11e into which lift pins for lifting the substrate W are inserted are formed in the body part 111. FIG. 3 illustrates a plurality of openings 52e corresponding to the plurality of cavities 11e into which the lift pins are inserted. The lift pin inserted into the cavity 11e is an example of a structure disposed in the cavity 11e.

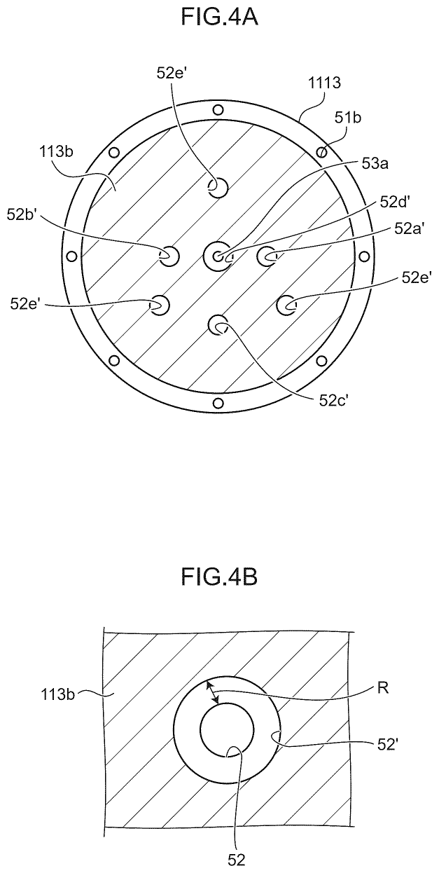

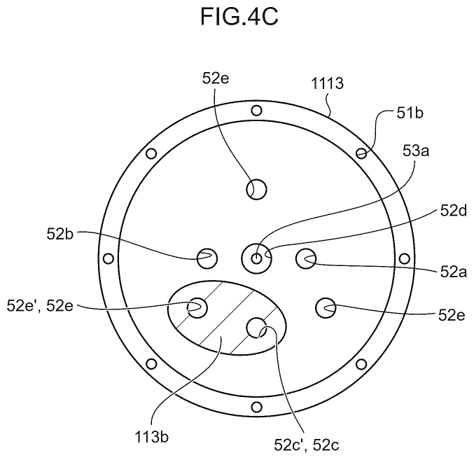

A sealing layer 113b is disposed on the support base 1113, for example, as illustrated in FIG. 2. FIG. 4A is a view illustrating an example of the sealing layer 113b disposed on the support base 1113. In FIG. 4A, the sealing layer 113b is hatched with oblique lines. For example, as illustrated in FIG. 4A, the sealing layer 113b is a sheet-like member in which openings 52a′ to 52e′ are formed in regions corresponding to the openings 52a to 52e on the upper surface of the support base 1113. The sealing layer 113b has elasticity and functions as a sealing material.

Hereinafter, the openings 52a to 52e of the support base 1113 will be collectively referred to as an opening 52 when not distinguished, and the openings 52a′ to 52e′ of the sealing layer 113b will be collectively referred to as an opening 52′when not distinguished. The opening 52′is an example of a through hole.

FIG. 4B is an enlarged view illustrating an example of a positional relationship between the opening 52 of the support base 1113 and the opening 52′of the sealing layer 113b. The opening 52′of the sealing layer 113b is larger than the opening 52 of the support base 1113, for example, as illustrated in FIG. 4B. Therefore, a region R where the sealing layer 113b is not disposed exists around the opening 52 on the upper surface of the support base 1113. As a result, contact between the sealing layer 113b and a member passing through the opening 52 of the support base 1113 or a member disposed in the opening 52 of the support base 1113 is suppressed.

As long as the sealing layer 113b is disposed in the entire region surrounding at least two or more openings 52 on the upper surface of the support base 1113, for example, the sealing layer 113b may be disposed in a partial region of the upper surface of the support base 1113 as illustrated in FIG. 4C. In the example of FIG. 4C, the sealing layer 113b is disposed in a region surrounding the opening 52c and the opening 52e of the support base 1113. Also in the example of FIG. 4C, the positional relationship between the openings 52c and 52e of the support base 1113 and the openings 52c′ and 52e′ of the sealing layer 113b is the same as that in FIG. 4B. Furthermore, in the example of FIG. 4C, each of the openings 52 not surrounded by the sealing layer 113b may be sealed via, for example, an annular seal. The annular seal includes an O-ring. The annular seal is disposed, for example, in a groove formed in the support base 1113 or the RF plate 1112 around the opening 52. In addition, in the example of FIG. 4A, the sealing layer 113b is disposed in a region positioned on an inner side of a region where the plurality of screw holes 51b are disposed on the upper surface of the support base 1113, but the sealing layer 113b may also be disposed in the region where the plurality of screw holes 51b are disposed on the upper surface of the support base 1113. Furthermore, a shape of the sealing layer 113b disposed on the upper surface of the support base 1113 is not limited to a circular shape or an elliptical shape, and any shape such as a triangular shape, a quadrangular shape, a polygonal shape, or a star shape can be adopted.

For example, as illustrated in FIG. 2, the RF plate 1112 is disposed on the support base 1113 and the sealing layer 113b. The RF plate 1112 is also formed with the cavity 11a and the cavity 11b serving as the channels for allowing the heat transfer medium to flow, the cavity 11c serving as the channel for allowing the heat transfer gas to flow, and the cavity 11d in which the electric wire for transmitting an electric signal such as the RF signal is disposed.

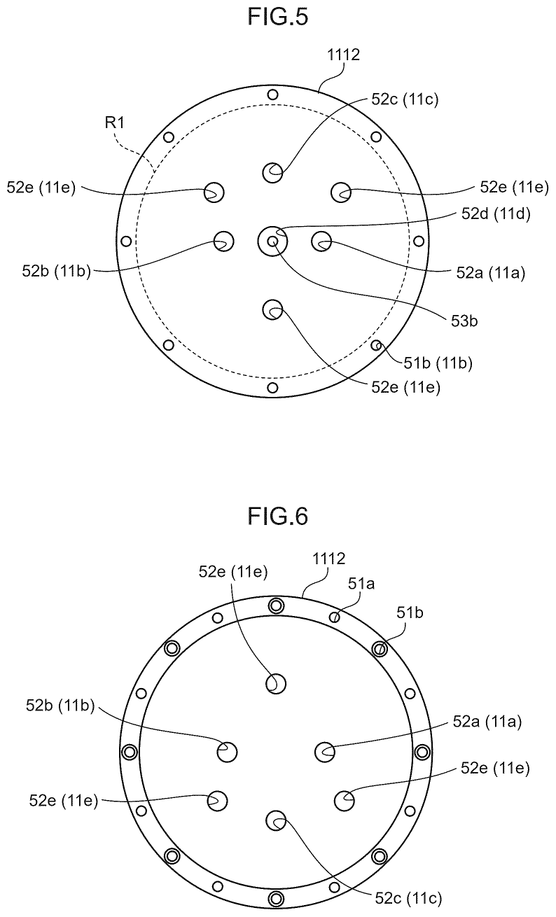

FIG. 5 is a view illustrating an example of a lower surface of the RF plate 1112. On the lower surface of the RF plate 1112, for example, as illustrated in FIG. 5, the openings 52a to 52e are formed at positions corresponding to the cavities 11a to 11e formed in the RF plate 1112. The plurality of screw holes 51b into which the screws 50b for fastening the support base 1113 and the RF plate 1112 are inserted are formed in a peripheral edge portion of the RF plate 1112. In a case where the RF plate 1112 is placed on the support base 1113 on which the sealing layer 113b is disposed, the sealing layer 113b is positioned in a region R1 indicated by a broken line in FIG. 5 except for regions where the openings 52a to 52e are formed.

The RF plate 1112 and the support base 1113 overlap each other with the sealing layer 113b interposed therebetween, and are fastened by the plurality of screws 50b. As a result, the cavities 11a to 11e formed in the RF plate 1112 and the cavities 11a to 11e formed in the support base 1113 communicate with each other via the openings 52a′ to 52e′ formed in the sealing layer 113b. The sealing layer 113b in which openings 52a′ to 52e′ are formed is disposed between the RF plate 1112 and the support base 1113. As a result, a fluid flowing through the cavities 11a to 11c is suppressed from leaking into a gap between the RF plate 1112 and the support base 1113, and the gas that has entered the cavity 11d and the cavity 11e is suppressed from leaking into the gap between the RF plate 1112 and the support base 1113.

Here, the sealing layer 113b in one or more embodiments is, for example, as illustrated in FIG. 4A, a sheet-like elastic member in which the openings 52a′ to 52e′ are formed. Therefore, the sealing layer 113b can be easily disposed on the upper surface of the support base 1113. Therefore, as compared with a case where one O-ring is disposed around each of the openings 52a to 52e of the support base 1113, a material having a sealing function can be more easily disposed around each of the openings 52a to 52e.

Further, in a case where the O-ring is disposed, it is necessary to perform machining for forming a recess having a shape along a shape of the O-ring on the upper surface of the support base 1113 or the lower surface of the RF plate 1112 in order to prevent displacement of the position of the O-ring. On the other hand, since the sealing layer 113b of one or more embodiments is a sheet-like member, a position thereof is hardly displaced.

Therefore, it is not necessary to form a recess around each of the openings 52a to 52e on the upper surface of the support base 1113 or the lower surface of the RF plate 1112. Therefore, it is not necessary to perform complicated machining on the support base 1113 and the RF plate 1112, and the placing pedestal can be easily manufactured.

A structure of the body part 111 will be continuously described. FIG. 6 is a view illustrating an example of an upper surface of the RF plate 1112. On the upper surface of the RF plate 1112, for example, as illustrated in FIG. 6, the opening 52a corresponding to the cavity 11a, the opening 52b corresponding to the cavity 11b, the opening 52c corresponding to the cavity 11c, and the opening 52e corresponding to the cavity 11e into which the lift pin is inserted are formed. The plurality of screw holes 51b into which the screws 50b for fastening the RF plate 1112 and the support base 1113 are inserted are formed in a peripheral edge portion of the upper surface of the RF plate 1112. A plurality of screw holes 51a into which screws 50a for fastening the base 1110 and the RF plate 1112 are inserted are formed in the peripheral edge portion of the upper surface of the RF plate 1112.

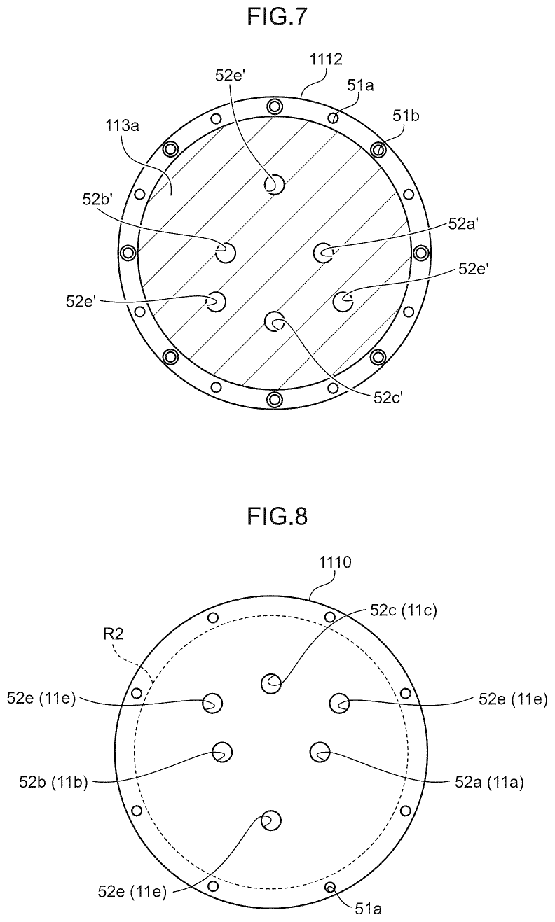

A sealing layer 113a is disposed on the RF plate 1112, for example, as illustrated in FIG. 2. FIG. 7 is a view illustrating an example of the sealing layer 113a disposed on the RF plate 1112. In FIG. 7, the sealing layer 113a is hatched with oblique lines. As illustrated in FIG. 7, for example, the sealing layer 113a is a sheet-like member in which the openings 52a′ to 52c′ and the opening 52e′ are formed in regions corresponding to the openings 52a to 52c and the opening 52e on the upper surface of the RF plate 1112. The sealing layer 113a is made of the same material as the sealing layer 113b. In the example of FIG. 7, on the upper surface of the RF plate 1112, the sealing layer 113a is disposed in a region positioned on an inner side of a region where the plurality of screw holes 51a and screw holes 51b are disposed. However, the disclosed technology is not limited thereto, and the sealing layer 113a may also be disposed in a region where the plurality of screw holes 51a and the plurality of screw holes 51b are disposed, on the upper surface of the RF plate 1112.

As illustrated in FIG. 2, for example, the base 1110 is disposed on the RF plate 1112 and the sealing layer 113a. The base 1110 is also formed with the cavity 11a and the cavity 11b serving as the channels for allowing the heat transfer medium to flow, and the cavity 11c serving as the channel for allowing the heat transfer gas to flow.

Although not illustrated in FIG. 2, the plurality of cavities 11e into which the lift pins are inserted are also formed in the base 1110.

FIG. 8 is a view illustrating an example of a lower surface of the base 1110. On the lower surface of the base 1110, for example, as illustrated in FIG. 8, the openings 52a to 52c and the opening 52e are formed at positions corresponding to the cavities 11a to 11c and the cavity 11e formed in the RF plate 1112. The plurality of screw holes 51a into which the screws 50a for fastening the base 1110 and the RF plate 1112 are inserted are formed in a peripheral edge portion of the lower surface of the base 1110. In a case where the base 1110 is placed on the RF plate 1112 on which the sealing layer 113a is disposed, the sealing layer 113a is positioned in a region R2 indicated by a broken line in FIG. 8 except for regions where the openings 52a to 52c and the opening 52e are formed.

The base 1110 and the RF plate 1112 overlap each other with the sealing layer 113a interposed therebetween, and are fastened by the plurality of screws 50a. As a result, the cavities 11a to 11c and the cavity 11e formed in the RF plate 1112 and the cavities 11a to 11c and the cavity 11e formed in the base 1110 communicate with each other via the openings 52a′ to 52c′ and the opening 52e′ formed in the sealing layer 113a. The sealing layer 113a in which the openings 52a′ to 52c′ and the opening 52e′ are formed is disposed between the base 1110 and the RF plate 1112. As a result, the fluid flowing through the cavities 11a to 11c is suppressed from leaking into a gap between the base 1110 and the RF plate 1112. In addition, the gas that has entered the cavity 11d and the cavity 11e is suppressed from leaking between the base 1110 and the RF plate 1112.

For example, as illustrated in FIG. 2, the electrostatic chuck 1111 is disposed on the base 1110. An O-ring 111c is disposed between the electrostatic chuck 1111 and the base 1110 and around the cavity 11c through which the heat transfer gas flows. An O-ring 111f is disposed between a lower surface of the support base 1113 and the bottom portion of the plasma processing chamber 10 and around the cavity 11c through which the heat transfer gas flows. In addition, O-rings 111d and 111e are disposed between the lower surface of the support base 1113 and the bottom portion of the plasma processing chamber 10 and around the cavities 11a and 11b through which the heat transfer medium flows, respectively.

In one or more embodiments, the sealing layer 113a and the sealing layer 113b are made of a material having a sufficient elastic characteristic as a sealing material even in a low-temperature environment of, for example, lower than 0° C. As a result, even in a case where temperatures of the base 1110, the RF plate 1112, and the support base 1113 become low due to the heat transfer medium flowing in the channel 1110a of the base 1110, the sealing layer 113a and the sealing layer 113b can maintain sufficient sealability.

As the material of the sealing layer 113a and the sealing layer 113b, for example, a material containing silicone can be used. Examples of the material containing silicone include modified silicone rubber. Vinyl methyl silicone rubber (VQM), fluorovinyl methyl silicone rubber (FVQM), or the like can be used as the modified silicone rubber.

### Procedure of Manufacturing Body Part 111

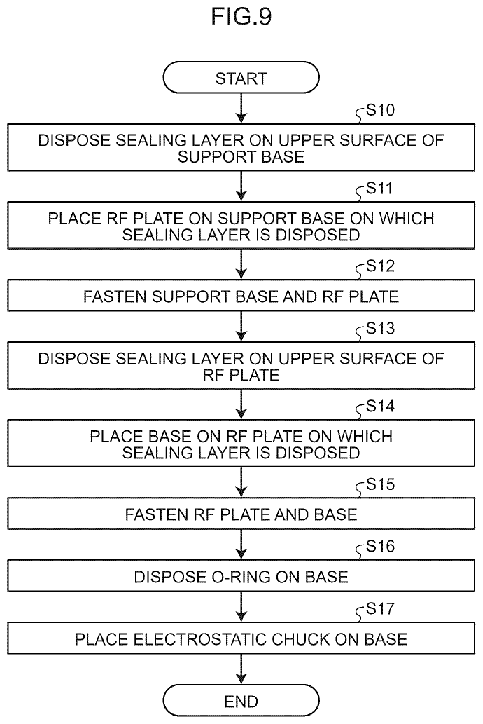

FIG. 9 is a flowchart illustrating an example of a procedure of manufacturing the body part 111 of the substrate support part 11. The procedure illustrated in FIG. 9 is an example of the member manufacturing method.

First, the support base 1113 is prepared, and the sheet-like sealing layer 113b is disposed on the upper surface of the support base 1113 (S10). Step S10 is an example of step a). In step S10, the sheet-like sealing layer 113b is disposed in the entire region excluding the openings 52a to 52e on the upper surface of the support base 1113.

Next, the RF plate 1112 is placed on the support base 1113 on which the sealing layer 113b is disposed (S11). Then, the support base 1113 and the RF plate 1112 are fastened by the plurality of screws 50b (S12). Step S13 is an example of step b).

Here, the RF plate 1112 and the support base 1113 may thermally expand due to temperature changes of the RF plate 1112 and the support base 1113 when the substrate W is processed. Outer peripheral portions of the RF plate 1112 and the support base 1113 are fastened by the plurality of screws 50b. Therefore, even when the RF plate 1112 and the support base 1113 thermally expand, a size of the gap between the RF plate 1112 and the support base 1113 hardly changes. However, at a position away from a fastening position, displacement may occur such that the gap between the RF plate 1112 and the support base 1113 becomes large due to a difference in expansion coefficient between the RF plate 1112 and the support base 1113. When the gap between the RF plate 1112 and the support base 1113 becomes large, a gap may be generated between the RF plate 1112 or the support base 1113 and the sealing layer 113b.

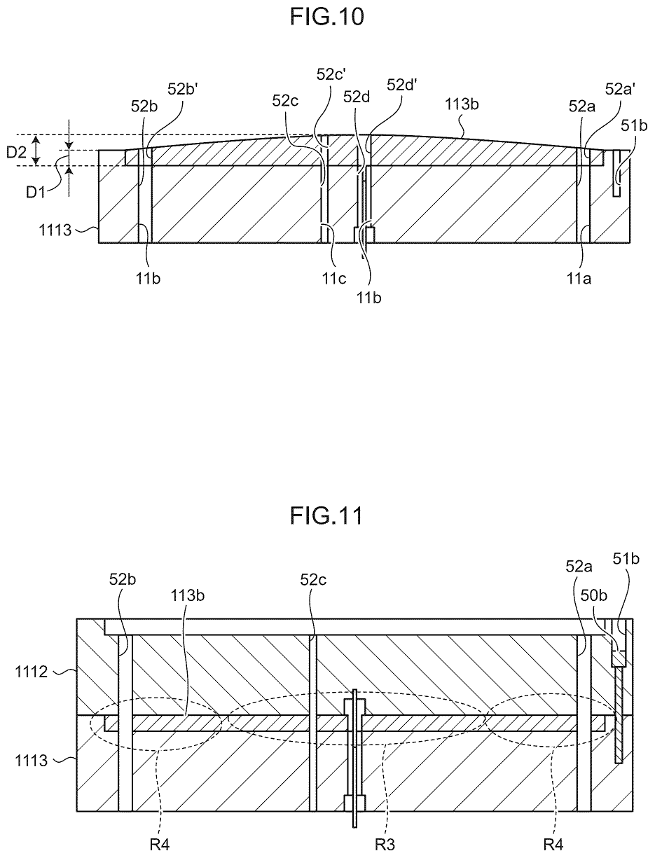

Therefore, in step S10, the sheet-like sealing layer 113b formed such that a portion disposed in a region far from the fastening position is thicker than a portion disposed in a region close to the fastening position is disposed on the upper surface of the support base 1113. For example, as illustrated in FIG. 10, the sealing layer 113b having a shape in which a thickness D2 in the region far from the fastening position is larger than a thickness D1 in the region close to the fastening position is disposed on the upper surface of the support base 1113.

Then, in step S12, the RF plate 1112 and the support base 1113 are fastened by the screws 50b, so that the RF plate 1112 and the support base 1113 have a structure illustrated in FIG. 11, for example. At this time, the sealing layer 113b in a region R3 far from the fastening position has a larger amount of change in thickness due to crushing, as compared with the sealing layer 113b in a region R4 close to the fastening position. That is, a compressive force is applied to the sealing layer 113b in a direction along a direction from the support base 1113 toward the RF plate 1112, and the amount of change in thickness of the sealing layer 113b in a case where the compressive force decreases is larger at a portion closer to the center of the upper surface of the support base 1113. Therefore, in the region R3, even if the size of the gap between the RF plate 1112 and the support base 1113 increases due to the difference in expansion coefficient, the thickness of the sealing layer 113b increases following the increase in size of the gap. As a result, even if the gap between the RF plate 1112 and the support base 1113 increases due to thermal expansion, the sealability in the region R3 far from the fastening position can be maintained.

Next, the sheet-like sealing layer 113a is disposed on the upper surface of the RF plate 1112 (S13). In step S13, the sheet-like sealing layer 113b is disposed in the region excluding the openings 52a to 52e on the upper surface of the RF plate 1112. Also in step S13, as in step S10, the sheet-like sealing layer 113a formed such that a portion disposed in a region far from the fastening position is thicker than a portion disposed in a region close to the fastening position is disposed on the upper surface of the RF plate 1112.

Next, the base 1110 is placed on the RF plate 1112 on which the sealing layer 113a is disposed (S14). Then, the RF plate 1112 and the base 1110 are fastened by the plurality of screws 50a (S15).

Next, the O-ring 111c is disposed around each of the openings corresponding to the cavities 11c and 11e on the upper surface of the base 1110 (S16). Then, the electrostatic chuck 1111 is placed on the base 1110 (S17), and the procedure of manufacturing the body part 111 shown in this flowchart ends.

One or more embodiments have been described above. As described above, the member (body part 111) in one or more embodiments is a member used in the semiconductor manufacturing apparatus (plasma processing apparatus 1), and includes the first member (RF plate 1112 and support base 1113), the second member (base 1110 and RF plate 1112), and the sealing layer (sealing layers 113a and 113b) disposed between the first member and the second member. The first member has a plurality of first openings, and the second member has a plurality of second openings respectively corresponding to the plurality of first openings. The sealing layer has a plurality of through holes respectively corresponding to at least two of the plurality of first openings. The at least two first openings respectively communicate with at least two corresponding second openings via the plurality of through holes. As a result, it is possible to provide the member that is easy to manufacture.

In the above one or more embodiments, the screw for fastening the first member and the second member is disposed at a peripheral edge of a surface of the first member on a second member side. The sealing layer is disposed on the surface of the first member on the second member side except for a region where the screw is disposed.

In the above one or more embodiments, an opening size of the through hole is larger than sizes of the corresponding first opening and second opening in a direction along the surface of the first member on the second member side. As a result, contact between the sealing layer 113b and the fluid passing through the through hole or the structure disposed in the through hole is suppressed.

In the above one or more embodiments, among the plurality of first openings, a first opening that does not communicate with the through hole may communicate with the corresponding second opening via an annular seal.

In the above one or more embodiments, the sealing layer may be formed in a sheet shape (i.e., planar shape).

In the above one or more embodiments, at least one of the first member and the second member is controlled to a temperature of lower than 0° C., and the sealing layer is modified silicone rubber. As a result, even when the sealing layer has a low temperature, elasticity can be maintained and sealability can be maintained.

In the above one or more embodiments, the compressive force is applied to the sealing layer in a direction from the first member toward the second member, and the amount of change in thickness of the sealing layer in a case where the compressive force decreases is larger at a portion closer to the center of the surface of the first member on the second member side. As a result, even in a case where a size of a gap between the first member and the second member increases due to thermal expansion, the sealing layer can maintain the sealability for the gap between the first member and the second member.

In addition, the above one or more embodiments is a placing pedestal including the above-described member, in which the second member is disposed on the first member. The placing pedestal further includes an electrostatic chuck disposed on the second member and configured such that a substrate is placed on an upper surface of the electrostatic chuck. The first member is an RF plate configured to be supplied with radio frequency (RF) power. A refrigerant flows through the through hole of the sealing layer. The second member is a cooling plate configured to cool the substrate via the electrostatic chuck by the refrigerant flowing through the through hole. As a result, it is possible to easily manufacture the placing pedestal including the base 1110, the electrostatic chuck 1111, and the RF plate 1112.

In addition, the above one or more embodiments is a placing pedestal including the above-described member, in which the first member is the support base 1113 configured to support the second member, and the second member is the RF plate 1112 configured to be supplied with the RF power. As a result, it is possible to easily manufacture the placing pedestal including the RF plate 1112 and the support base 1113.

In addition, the above one or more embodiments is a semiconductor manufacturing apparatus including a placing pedestal including the above-described member. Therefore, it is possible to easily manufacture the semiconductor manufacturing apparatus.

The member manufacturing method according to the above one or more embodiments includes steps a) and b). In step a), the sealing layer is disposed on the upper surface of the first member. In step b), the first member and the second member are fastened with the sealing layer interposed therebetween. In addition, the first member has the plurality of first openings, and the second member has the plurality of second openings respectively corresponding to the plurality of first openings. In step a), the sealing layer is disposed in a region that surrounds at least two first openings among the plurality of first openings and excludes the at least two first openings. Therefore, it is possible to easily manufacture the member.

In the above one or more embodiments, the screw for fastening the first member and the second member is disposed at the peripheral edge of the surface of the first member on the second member side, and the sealing layer is disposed on the surface of the first member on the second member side except for the region where the screw is disposed.

In the above one or more embodiments, a size of an opening of the sealing layer is larger than the sizes of the corresponding first opening and second opening in a direction along the surface of the first member on the second member side.

In the above one or more embodiments, among the plurality of first openings, a first opening that does not communicate with the opening of the sealing layer communicates with the corresponding second opening via the annular seal.

In the above one or more embodiments, in step a), the sheet-like sealing layer in which the through holes are formed in regions corresponding to the first opening and the second opening is disposed on a surface of the first member or a surface of the second member. Therefore, it is possible to easily manufacture the member.

In the above one or more embodiments, in step b), the second member is fastened to the first member, and the shape of the sealing layer disposed in step a) is a shape in which a thickness of the sealing layer in a region far from the fastening position is larger than a thickness of the sealing layer in a region close to the fastening position. As a result, even in a case where a size of a gap between the first member and the second member increases due to thermal expansion, the sealing layer can maintain the sealability for the gap between the first member and the second member.

### Others

The technology disclosed in the present application is not limited to the above one or more embodiments, and various modifications can be made within the scope of the gist of the present invention.

For example, in the above one or more embodiments, the sealing layers formed in the sheet shape in advance are disposed on the upper surface of the support base 1113 and the upper surface of the RF plate 1112, but the disclosed technology is not limited thereto. As another form, liquid modified silicone rubber as the material of the sealing layer may be applied to the upper surface of the support base 1113 and the upper surface of the RF plate 1112, and the applied material may be cured to dispose the sealing layers on the upper surface of the support base 1113 and the upper surface of the RF plate 1112.

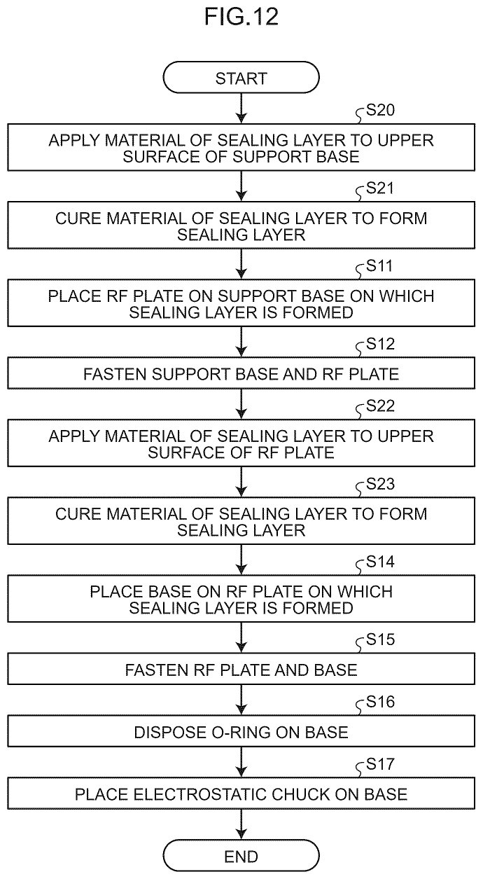

In this case, the sealing layers may be disposed on the upper surface of the support base 1113 and the upper surface of the RF plate 1112, for example, in the procedure illustrated in FIG. 12. FIG. 12 is a flowchart illustrating another example of the procedure of manufacturing the body part 111 of the substrate support part 11. Except for the points described below, in FIG. 12, processing denoted with the same reference numeral as FIG. 9 is similar to the processing described in FIG. 9, and thus a description thereof is omitted.

First, the support base 1113 is prepared, and the liquid modified silicone rubber as the material of the sealing layer 113b is applied to the upper surface of the support base 1113 (S20). Step S20 is an example of step a). In addition, the application in step S20 is an example of a method of disposing the sealing layer 113b. In step S20, the liquid modified silicone rubber is applied to the entire region excluding the openings 52a to 52e on the upper surface of the support base 1113.

Next, the liquid modified silicone rubber applied to the upper surface of the support base 1113 is cured to form the sealing layer 113b on the upper surface of the support base 1113 (S21). In step S21, the liquid modified silicone rubber applied to the upper surface of the support base 1113 is cooled to about room temperature, so that the liquid modified silicone rubber is cured into rubber-like modified silicone rubber having elasticity to become the sealing layer 113b.

In step S20, the liquid modified silicone rubber is applied to the upper surface of the support base 1113 such that a thickness of the modified silicone rubber in a region far from the fastening position is larger than a thickness of the modified silicone rubber in a region close to the fastening position. Then, in step S21, the modified silicone rubber is cured. As a result, for example, as illustrated in FIG. 10, the sealing layer 113b having a shape in which the thickness D2 in the region far from the fastening position is larger than the thickness D1 in the region close to the fastening position is formed on the upper surface of the support base 1113.

Then, in step S12, after the RF plate 1112 and the support base 1113 are fastened by the screws 50b, the liquid modified silicone rubber as the material of the sealing layer 113a is applied to the upper surface of the RF plate 1112 (S22). In step S22, the liquid modified silicone rubber is applied to a region excluding the openings 52a to 52e on the upper surface of the RF plate 1112. In step S22, similarly to step S20, the liquid modified silicone rubber is applied to the upper surface of the RF plate 1112 such that a thickness of the modified silicone rubber in a region far from the fastening position is larger than a thickness of the modified silicone rubber in a region close to the fastening position.

Next, the modified silicone rubber applied to the upper surface of the RF plate 1112 is cured to form the sealing layer 113a on the upper surface of the RF plate 1112 (S23). In step S23, the liquid modified silicone rubber applied to the upper surface of the RF plate 1112 is cooled to about room temperature, so that the liquid silicone rubber is cured into rubber-like modified silicone rubber having elasticity to form the sealing layer 113a. Then, steps of processing in and after step S14 are performed.

In a case where the sealing layer is formed by applying a liquid material, the liquid material applied to form the sealing layer may contain a colorant (for example, carbon-containing particles). Accordingly, in a case where the sealing layer is formed by application, a region where the liquid material is applied and a region where the liquid material is not applied can be easily distinguished from each other. Further, by applying the liquid material such that a color density of the liquid material is almost uniform, it is possible to suppress variation in film thickness of the sealing layer.

In the above one or more embodiments, after the sealing layer 113b is disposed on the upper surface of the support base 1113, the RF plate 1112 is placed on the support base 1113 on which the sealing layer 113b is disposed. In the above one or more embodiments, after the sealing layer 113a is disposed on the upper surface of the RF plate 1112, the base 1110 is placed on the RF plate 1112 on which the sealing layer 113a is disposed. However, the disclosed technology is not limited thereto. For example, as another form, after the sealing layer 113b is disposed on the lower surface of the RF plate 1112, the RF plate 1112 having the sealing layer 113b disposed on the lower surface may be placed on the support base 1113. Further, after the sealing layer 113a is disposed on the lower surface of the base 1110, the base 1110 having the sealing layer 113a disposed on the lower surface may be placed on the RF plate 1112.

In the above one or more embodiments, the O-rings are disposed between the base 1110 and the electrostatic chuck 1111 and between the support base 1113 and the bottom portion of the plasma processing chamber 10, but the disclosed technology is not limited thereto. Sealing layers similar to the sealing layers 113a and 113b may also be disposed between the base 1110 and the electrostatic chuck 1111 and between the support base 1113 and the bottom portion of the plasma processing chamber 10.

Furthermore, in the above one or more embodiments, at least one of the first member and the second member is controlled to a temperature lower than 0° C., but the disclosed technology is not limited thereto. As another form, at least one of the first member and the second member may be controlled to a temperature of 0° C. or higher. As the material of the sealing layer disposed between the first member and the second member in this case, for example, fluororubber can be used. As the fluororubber, vinylidene fluoride-based fluororubber (FKM), perfluoroelastomer (FFKM), or the like can be used. As a result, even when the sealing layer has a high temperature, elasticity can be maintained without melting, and sealability can be maintained.

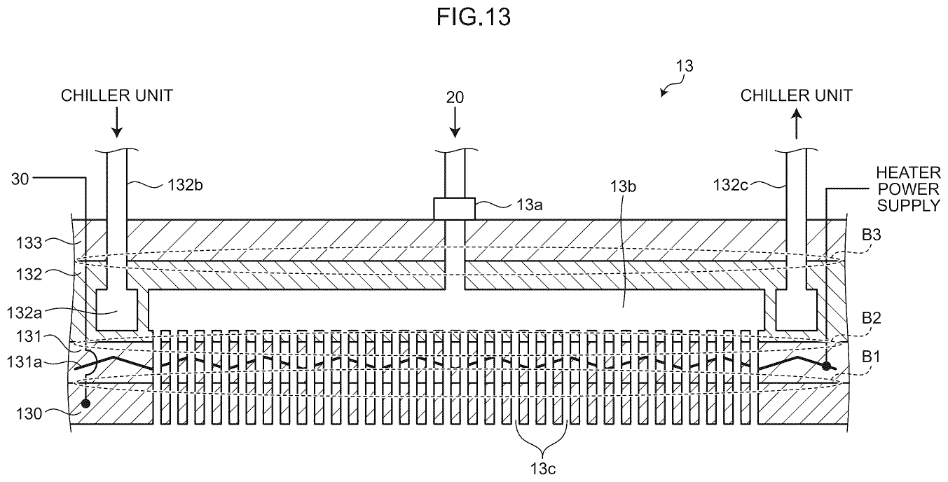

In the above one or more embodiments, the placing pedestal (body part 111) has been described as an example of the structure including the member, but the structure including the member is not limited to the placing pedestal. Another example of the structure including the member may be, for example, the shower head 13 included in the plasma processing apparatus 1 illustrated in FIG. 1. FIG. 13 is a schematic cross-sectional view illustrating an example of a structure of the shower head 13. The shower head 13 is an example of an upper unit. The shower head 13 includes, for example, an electrode plate 130, a heating layer 131, a cooling plate 132, and an upper member 133. A plurality of gas introduction ports 13c are formed in the electrode plate 130 and the heating layer 131, a heater 131a is embedded in the heating layer 131, and a heater power supply (not illustrated) is connected to the heater 131a. In addition to the gas diffusion chamber 13b, a channel 132a through which the refrigerant flows is formed in the cooling plate 132. A pipe 132b and a pipe 132c are connected to the channel 132a. The refrigerant supplied from a chiller unit (not illustrated) is supplied into the channel 132a via the pipe 132b, flows through the channel 132a, and is returned to the chiller unit (not illustrated) via the pipe 132c. The sealing layer may be disposed, for example, at an interface B1 between an upper surface of the electrode plate 130 and a lower surface of the heating layer 131. In this case, a portion including the electrode plate 130 and the heating layer 131 is an example of the member, the electrode plate 130 is an example of the first member, and the heating layer 131 is an example of the second member. The sealing layer may be disposed, for example, at an interface B2 between an upper surface of the heating layer 131 and a lower surface of the cooling plate 132. In this case, a portion including the heating layer 131 and the cooling plate 132 is an example of the member, the heating layer 131 is an example of the first member, and the cooling plate 132 is an example of the second member. The sealing layer may be disposed at an interface B3 between an upper surface of the cooling plate 132 and a lower surface of the upper member 133. In this case, a portion including the cooling plate 132 and the upper member 133 is an example of the member, the cooling plate 132 is an example of the first member, and the upper member 133 is an example of the second member.

Furthermore, in the above one or more embodiments, the plasma processing apparatus 1 that processes the substrate W using plasma has been described as an example, but the disclosed technology can also be applied to other processing apparatuses that do not use plasma as long as the apparatus processes the substrate W.

In the above one or more embodiments, the plasma processing apparatus 1 that performs processing by using capacitively coupled plasma (CCP) has been described as an example of a plasma source, but the plasma source is not limited thereto. Examples of the plasma source other than the capacitively coupled plasma include inductively coupled plasma (ICP), microwave-excited surface wave plasma (SWP), electron cyclotron resonance plasma (ECP), and helicon wave-excited plasma (HWP).

According to various aspects and one or more embodiments of the present disclosure, a member that is easy to assemble can be provided.

It should be understood that the exemplary embodiment disclosed herein is illustrative in all respects and is not restrictive. Indeed, the above exemplary embodiment may be embodied in various forms. The above exemplary embodiment may be omitted, replaced, or modified in various forms without departing from the scope and spirit of the appended claims. The present disclosure encompasses various modifications to each of the examples and embodiments discussed herein. According to the disclosure, one or more features described above in one embodiment or example can be equally applied to another embodiment or example described above. The features of one or more embodiments or examples described above can be combined into each of the embodiments or examples described above. Any full or partial combination of one or more embodiment or examples of the disclosure is also part of the disclosure.

In addition, regarding the above exemplary embodiment, the following supplementary notes are further disclosed.

### Supplementary Note 1

A member used in a semiconductor manufacturing apparatus, the member including:
a first member;
a second member; and
a sealing layer disposed between the first member and the second member, in which
the first member has a plurality of first openings,
the second member has a plurality of second openings respectively corresponding to the plurality of first openings,
the sealing layer has a plurality of through holes respectively corresponding to at least two first openings among the plurality of first openings, and
the at least two first openings respectively communicate with at least two corresponding second openings via the plurality of through holes.

### Supplementary Note 2

The member according to Supplementary Note 1, further comprising
a screw fastening the first member and the second member and disposed at a peripheral edge of a surface of the first member on a second member side, wherein
the sealing layer is disposed on the surface of the first member on the second member side except for a region where the screw is disposed.

### Supplementary Note 3

The member according to Supplementary Note 1 or 2, wherein an opening size of each through hole is larger than sizes of a corresponding one of the plurality of first openings and a corresponding one of the plurality of second openings in a direction along the surface of the corresponding first member on the second member side

### Supplementary Note 4

The member according to any one of Supplementary Notes 1 to 3, in which among the plurality of first openings, a first first opening that does not communicate with any of the plurality of through holes communicates with a corresponding one of the plurality of second openings via an annular seal.

### Supplementary Note 5

The member according to any one of Supplementary Notes 1 to 4, in which the sealing layer is formed in a planar sheet shape.

### Supplementary Note 6

The member according to any one of Supplementary Notes 1 to 5, in which
at least one of the first member and the second member is controlled to a temperature of lower than 0° C., and the sealing layer is modified silicone rubber.

### Supplementary Note 7

The member according to any one of Supplementary Notes 1 to 5, in which
at least one of the first member and the second member is controlled to a temperature of 0° C. or higher, and
the sealing layer is fluororubber.

### Supplementary Note 8

The member according to any one of Supplementary Notes 1 to 7, in which
a compressive force is applied to the sealing layer in a direction from the first member toward the second member, and
an amount of change in thickness of the sealing layer in a case where the compressive force decreases is larger at a portion closer to a center of the surface of the first member on the second member side.

### Supplementary Note 9

A placing pedestal including:
the member according to any one of Supplementary Notes 1 to 8, in which
the second member is disposed on the first member,
the placing pedestal further includes:
   an electrostatic chuck disposed on the second member and configured to receive a substrate on an upper surface of the electrostatic chuck; and
   a refrigerant flowing through the plurality of through holes,
the first member is a radio frequency (RF) plate configured to be supplied with RF power,
and
the second member is a cooling plate configured to cool the substrate via the electrostatic chuck by the refrigerant flowing through the through hole.

### Supplementary Note 10

A placing pedestal including:
the member according to any one of Supplementary Notes 1 to 8, in which
the first member is a support base configured to support the second member, and
the second member is an RF plate configured to be supplied with RF power.

### Supplementary Note 11

A semiconductor manufacturing apparatus including:
the placing pedestal according to Supplementary Note 9 or 10; and
a shower head.

### Supplementary Note 12

An upper unit including:
the member according to any one of Supplementary Note 1 to 8, in which
the first member is an electrode plate, and
the second member is a heating layer.

### Supplementary Note 13

A semiconductor manufacturing apparatus including:
the upper unit according to Supplementary Note 12; and
a shower head.

### Supplementary Note 14

A member manufacturing method including:
a step a) of disposing a sealing layer on a surface of a first member or a surface of a second member; and
a step b) of fastening the first member to the second member with the sealing layer interposed therebetween, in which
the first member has a plurality of first openings,
the second member has a plurality of second openings respectively corresponding to the plurality of first openings, and
in the step a), the sealing layer is disposed in a region that surrounds at least two first openings among the plurality of first openings and excludes the at least two first openings.

### Supplementary Note 15

The member manufacturing method according to Supplementary Note 14, in which
the first member and the second member are fastened to each other via a screw, and the screw is disposed at a peripheral edge of a surface of the first member on a second member side, and
the sealing layer is disposed on the surface of the first member on the second member side except for a region where the screw is disposed.

### Supplementary Note 16

The member manufacturing method according to the Supplementary Note 14 or 15, in which a size of an opening of the sealing layer is larger than sizes of the plurality of first openings and the plurality of second openings in a direction along the surface of the first member on the second member side.

### Supplementary Note 17

The member manufacturing method according to any one of Supplementary Notes 14 to 16, in which among the plurality of first openings, a first first opening that does not communicate with the opening of the sealing layer communicates with a corresponding one of the plurality of second openings via an annular seal.

### Supplementary Note 18

The member manufacturing method according to any one of the Supplementary Notes 14 to 17, wherein a) further comprises applying a liquid material for forming the sealing layer to an entire region that excludes the plurality of first openings and the plurality of second openings and surrounds at least two of the plurality of first openings on the surface of the first member or at least two of the plurality of second openings on the surface of the second member to dispose the sealing layer on the surface of the first member or the surface of the second member.

### Supplementary Note 19

The member manufacturing method according to Supplementary Note 18, in which the liquid material for forming the sealing layer contains a colorant.

### Supplementary Note 20

The member manufacturing method according to any one of Supplementary Notes 14 to 17, in which in the step a), the sheet-like sealing layer in which through holes are formed in regions corresponding to the first opening and the second opening is disposed on the surface of the first member or the surface of the second member.

### Supplementary Note 21

The member manufacturing method according to any one of Supplementary Notes 14 to 20, in which
in the step b), the second member is fastened to the first member, and
a thickness of the sealing layer in a region far from a fastening position is larger than a thickness of the sealing layer in a region close to the fastening position.

### Supplementary Note 22

The member manufacturing method according to any one of Supplementary Notes 14 to 21, in which
at least one of the first member and the second member is controlled to a temperature of lower than 0° C., and the sealing layer is modified silicone rubber.

### Supplementary Note 23

The member manufacturing method according to any one of Supplementary Notes 14 to 21, in which
at least one of the first member and the second member is controlled to a temperature of 0° C. or higher, and
the sealing layer is fluororubber.

### Supplementary Note 24

The member manufacturing method according to any one of Supplementary Notes 14 to 21, further comprising:
applying a compressive force to the sealing layer in a direction from the first member toward the second member, wherein
an amount of change in thickness of the sealing layer is larger at a portion closer to a center of the surface of the first member on the second member side.

What is claimed is:

1. A member used in a semiconductor manufacturing apparatus, the member comprising:
a first member;
a second member; and
a sealing layer disposed between the first member and the second member, wherein
the first member has a plurality of first openings,
the second member has a plurality of second openings respectively corresponding to the plurality of first openings,
the sealing layer has a plurality of through holes respectively corresponding to at least two first openings among the plurality of first openings, and
the at least two first openings respectively communicate with at least two corresponding second openings via the plurality of through holes.

2. The member according to claim 1, further comprising:
a screw fastening the first member and the second member and disposed at a peripheral edge of a surface of the first member on a second member side, wherein
the sealing layer is disposed on the surface of the first member on the second member side except for a region where the screw is disposed.

3. The member according to claim 1, wherein an opening size of each through hole is larger than sizes of a corresponding one of the plurality of first openings and a corresponding one of the plurality of second openings in a direction along the surface of the corresponding first member on the second member side.

4. The member according to claim 1, wherein among the plurality of first openings, a first first opening that does not communicate with any of the plurality of through holes communicates with a corresponding one of the plurality of second openings via an annular seal.

5. The member according to claim 1, wherein the sealing layer is formed in a planar sheet shape.

6. The member according to claim 1, wherein at least one of the first member and the second member is controlled to a temperature of lower than 0° C., and
the sealing layer is modified silicone rubber.

7. The member according to claim 1, wherein at least one of the first member and the second member is controlled to a temperature of 0° C. or higher, and
the sealing layer is fluororubber.

8. A placing pedestal comprising:
the member according to claim 1, wherein
the second member is disposed on the first member,
the placing pedestal further comprises:
an electrostatic chuck disposed on the second member and configured to receive a substrate on an upper surface of the electrostatic chuck; and
a refrigerant flowing through the plurality of through holes,
the first member is a radio frequency (RF) plate configured to be supplied with RF power,
and
the second member is a cooling plate configured to cool the substrate via the electrostatic chuck by the refrigerant flowing through the through hole.

9. A placing pedestal comprising:
the member according to claim 1, wherein
the first member is a support base configured to support the second member, and
the second member is an RF plate configured to be supplied with RF power.

10. A semiconductor manufacturing apparatus comprising:
the placing pedestal according to claim 9; and
a shower head.

11. An upper unit comprising:
the member according to claim 1, wherein
the first member is an electrode plate, and
the second member is a heating layer.

12. A semiconductor manufacturing apparatus comprising:
the upper unit according to claim 11; and
a shower head.

13. A member manufacturing method comprising:
a) disposing a sealing layer on a surface of a first member or a surface of a second member; and
b) fastening the first member to the second member with the sealing layer interposed therebetween, wherein
the first member has a plurality of first openings,
the second member has a plurality of second openings respectively corresponding to the plurality of first openings, and
in the a), the sealing layer is disposed in a region that surrounds at least two first openings among the plurality of first openings and excludes the at least two first openings.

14. The member manufacturing method according to claim 13, wherein
the first member and the second member are fastened to each other via a screw, and the screw is disposed at a peripheral edge of a surface of the first member on a second member side, and
the sealing layer is disposed on the surface of the first member on the second member side except for a region where the screw is disposed.

15. The member manufacturing method according to claim 13, wherein a size of an opening of the sealing layer is larger than sizes of the plurality of first openings and the plurality of second openings in a direction along the surface of the first member on the second member side.

16. The member manufacturing method according to claim 13, wherein among the plurality of first openings, a first first opening that does not communicate with the opening of the sealing layer communicates with a corresponding one of the plurality of second openings via an annular seal.

17. The member manufacturing method according to claim 13, wherein a) further comprises applying a liquid material for forming the sealing layer to an entire region that excludes the plurality of first openings and the plurality of second openings and surrounds at least two of the plurality of first openings on the surface of the first member or at least two of the plurality of second openings on the surface of the second member to dispose the sealing layer on the surface of the first member or the surface of the second member.

18. The member manufacturing method according to claim 13, wherein in the a), the sheet-like sealing layer in which through holes are formed in regions corresponding to the first opening and the second opening is disposed on the surface of the first member or the surface of the second member.

19. The member manufacturing method according to claim 13, wherein
a thickness of the sealing layer in a region far from a fastening position is larger than a thickness of the sealing layer in a region close to the fastening position.

20. The member manufacturing method according to claim 13, wherein
at least one of the first member and the second member is controlled to a temperature of lower than 0° C., and
the sealing layer is modified silicone rubber or is a fluororubber.

21. The member manufacturing method according to claim 13, further comprising:
applying a compressive force to the sealing layer in a direction from the first member toward the second member, wherein
an amount of change in thickness of the sealing layer is larger at a portion closer to a center of the surface of the first member on the second member side.
